(19) United States
(12) Patent Application Publication
(10) Pub. No.: US 2010/0055850 A1
(43) Pub. Date: Mar. 4, 2010

(54) METHODS FOR FABRICATING PIXEL STRUCTURE, DISPLAY PANEL AND ELECTRO-OPTICAL APPARATUS

(75) Inventors: Yi-Chen Chiang, Chiayi County (TW); Chih-Hung Shih, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/265,694

(22) Filed: Nov. 5, 2008

(30) Foreign Application Priority Data
Aug. 29, 2008 (TW) 97133287

(51) Int. Cl. H01L 21/84

(52) U.S. Cl. 438/155; 257/E21.7

(57) ABSTRACT

A substrate having a switching device and a storage capacitor thereon is provided. A protective layer is formed on the substrate. A patterned organic material layer is formed on the protective layer, wherein bump patterns are formed on a part of the patterned organic material layer and the patterned organic material layer has first openings to expose the partial protective layer. A reflective layer is formed on the patterned organic material layer and the exposed protective layer. A first patterned photoresist layer is formed on a part of the reflective layer, wherein the first patterned photoresist layer has second openings to expose a part of the reflective layer. The first patterned photoresist layer is used as an etching mask to form a first contact hole and a second contact hole. The first patterned photoresist layer is removed. A pixel electrode is formed on the patterned organic material layer.

### CROSS-REFERENCE TO RELATED APPLICATION

This application claims the priority benefit of Taiwan application serial no. 97133287, filed on Aug. 29, 2008. The entirety of the above-mentioned patent application is hereby incorporated by reference herein and made a part of specification.

### BACKGROUND OF THE INVENTION

1. Field of the Invention

The present invention generally relates to methods for fabricating a pixel structure, a display panel and an electro-optical apparatus, and more particularly, to a method of fabricating a transflective pixel structure or a reflective pixel structure and a method of a fabricating display panel and an electro-optical apparatus adopting the above-mentioned pixel structure.

2. Description of Related Art

A thin film transistor liquid crystal display (TFT-LCD) is usually categorized into transmissive one, reflective one and transflective one according to the types of light source and the array substrate thereof. In general, a transmissive TFT-LCD employs a backlight source as the light source thereof, wherein the pixel electrodes on the TFT array substrate thereof are transparent electrodes to facilitate the light emitted from the backlight source passing through. A reflective TFT-LCD mainly employs a front-light source or an external light source (i.e. environment light source or ambient light source) as the light source thereof, wherein the pixel electrodes on the TFT array substrate are reflective electrodes made of metal or other materials with good reflectivity so as to reflect the light emitted from the front-light source or the external light source. A transflective TFT-LCD can be seen as an integrated architecture of a transmissive TFT-LCD and a reflective TFT-LCD, wherein both the backlight source and the front-light source/the external light source are used for displaying.

The method of fabricating a pixel structure of a conventional reflective TFT-LCD or a conventional transflective TFT-LCD includes following steps. First, a TFT is formed on a substrate. Next, a protective layer is formed on the substrate to cover the TFT. Then, a first patterned photoresist layer with an opening is formed on the protective layer, wherein the opening exposes the partial protective layer over the drain of the TFT. Then, an etching process on the exposed part of the protective layer is conducted to form a contact hole so as to expose the drain of the TFT and the first patterned photoresist layer is removed. Then, a patterned organic material layer is formed on the protective layer, wherein a plurality of bump patterns are formed on the surface of the patterned organic material layer and the patterned organic material layer has an opening therein to expose the contact hole in the protective layer. Then, a reflective layer is formed on the patterned organic material layer by depositing. Then, a second patterned photoresist layer with an opening is formed on the reflective layer to expose a part of the reflective layer over the drain of the TFT and the exposed part of the reflective layer is removed by etching so as to expose the drain of the TFT, and then the second patterned photoresist layer is removed. Finally, a patterned pixel electrode is formed on the reflective layer, wherein the patterned pixel electrode is electrically connected to the drain of the TFT via the opening in the organic material layer and the contact hole in the protective layer.

According to the above-mentioned fabricating process, first, conducting a patterning step on the protective layer to expose the drain of the TFT; next, after forming the reflective layer, conducting a patterning step on the reflective layer. Therefore, the above-mentioned conventional fabricating process respectively requires a photolithograph process on the protective layer and the reflective layer, where two patterned photoresist layers are required.

In addition, since the above-mentioned fabricating process of a pixel structure needs, first, to conduct a patterning step on the protective layer to expose the drain of the TFT. Therefore, as a successive etching step on the reflective layer is conducted, the exposed drain must be avoided from being damaged by the conducted etching; and to achieve the objective, titanium is used as the upper layer material of the metal layer in the conventional pixel structure. However, to pattern the metal layer having the titanium upper layer, a dry etching process is required, which largely reduces the production capability of the pixel structure.

### SUMMARY OF THE INVENTION

Accordingly, the present invention is directed to a method of fabricating a pixel structure capable of reducing the process time and increasing the production capability.

The present invention is also directed to a method of fabricating a display panel which has the above-mentioned pixel structure.

The present invention is further directed to a method of fabricating an electro-optical apparatus which has the above-mentioned display panel.

To achieve the above-mentioned or other objectives, the present invention provides a method of fabricating a pixel structure. First, a substrate is provided, wherein a switching device and a storage capacitor have been formed on the substrate already. Next, a protective layer is formed on the substrate, wherein the protective layer covers the switching device and the storage capacitor. Next, a patterned organic material layer is formed on the protective layer, wherein a plurality of bump patterns are formed on a part of the patterned organic material layer and the patterned organic material layer has a plurality of first openings. The first openings respectively expose the partial protective layer located over a source/drain and the partial protective layer located over the upper electrode of the storage capacitor. Next, a reflective layer is formed on the patterned organic material layer and the exposed part of the protective layer. Thereafter, a first patterned photoresist layer is formed on a part of the reflective layer, wherein the first patterned photoresist layer has a plurality of second openings. The second openings expose a part of the reflective layer and each of the second openings is substantially corresponding to each of the first openings. Next, the first patterned photoresist layer is used as an etching mask to remove the exposed part of the reflective layer and the part of the protective layer located under the exposed part of the reflective layer so as to form a first contact hole exposing the source/drain of the switching device and form a second contact hole exposing the upper electrode of the storage capacitor. Next, the first patterned photoresist layer is removed. Finally, a pixel electrode is formed on the patterned organic material layer, wherein the pixel electrode is electrically connected to the source/drain of the switching device via the first contact hole and to the upper electrode of the storage capacitor via the second contact hole.

In an embodiment of the present invention, the above-mentioned step of removing the exposed part of the reflective layer and the protective layer under the exposed part of the reflective layer is conducted by using an in-situ process.

In an embodiment of the present invention, the above-mentioned step of forming the patterned organic material layer is to conduct an exposing process on an organic material layer by using a grey level photomask.

In an embodiment of the present invention, the above-mentioned method of forming the switching device and the storage capacitor includes: first, forming a first metal layer on the substrate, wherein the first metal layer includes a gate and a lower electrode; next, forming an insulating layer on the first metal layer; then, forming an active layer on the insulating layer over the gate; finally, forming a second metal layer on the insulating layer, wherein the second metal layer includes the source/drain over a part of the active layer and the upper electrode over the lower electrode.

In an embodiment of the present invention, the above-mentioned method of forming the switching device and the storage capacitor includes: first, forming a first metal layer on the substrate, wherein the first metal layer includes a gate and a lower electrode; next, sequentially forming an insulating layer, a semiconductor layer and a second metal layer on the first metal layer; then, forming a second patterned photoresist layer on the second metal layer, wherein the second patterned photoresist layer has a first portion and a second portion, the first portion is located over the gate, and the second portion covers two parts of the second metal layer located at both sides of the gate and a part of the second metal layer over the lower electrode; after that, taking the second patterned photoresist layer as a mask to pattern the second metal layer and the semiconductor layer so as to define an active layer over the gate and an upper electrode over the lower electrode; further, conducting an ashing process on the second patterned photoresist layer to remove the first portion; finally, taking the second portion of the second patterned photoresist layer as a mask to remove the second metal layer over the active layer so as to define the source and the drain.

In an embodiment of the present invention, the above-mentioned step of forming the second patterned photoresist layer is to conduct an exposing process on a photoresist layer by using a grey level photomask.

The present invention provides a method of fabricating a display panel. The method includes the above-mentioned fabricating method of a pixel structure.

The present invention provides a method of fabricating an electro-optical apparatus. The method includes the above-mentioned fabricating method of a display panel.

In summary, since the present invention uses a single patterned photoresist layer or the same patterned photoresist layer as an etching mask to sequentially remove the exposed part of the reflective layer and the part of the protective layer located under the exposed part of the reflective layer, therefore, in comparison with the conventional method of fabricating a pixel structure of a reflective LCD, the method of fabricating a pixel structure of the present invention is able to save at least a photolithograph process to reduce the fabricating time and increase the production capability. In addition, the present invention has another advantage of avoiding the second metal layer from being eroded by etching fluid due to the protection of the protective layer.

### BRIEF DESCRIPTION OF THE DRAWINGS

The accompanying drawings are included to provide a further understanding of the invention, and are incorporated in and constitute a part of this specification. The drawings illustrate embodiments of the present invention and, together with the description, serve to explain the principles of the invention.

FIGS. 1A-1L are sectional diagrams illustrating the method of fabricating a pixel structure according to an embodiment of the present invention.

FIGS. 2A-2N are sectional diagrams illustrating the method of fabricating a pixel structure according to another embodiment of the present invention.

FIG. 3 is a diagram of a display panel according to an embodiment of the present invention.

FIG. 4 is a diagram of an electro-optical apparatus according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

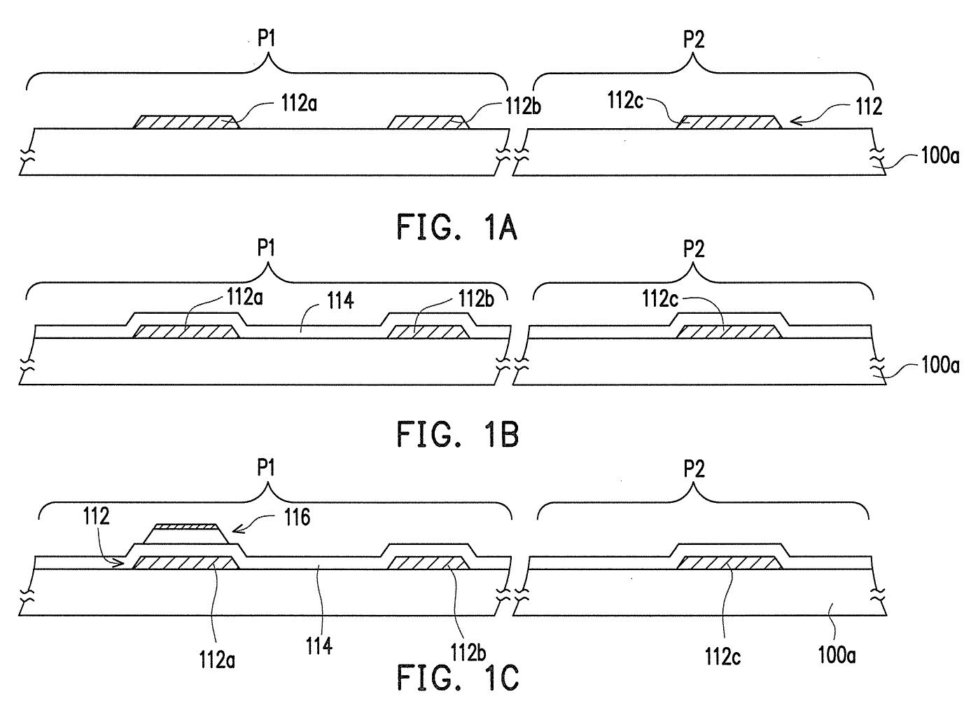

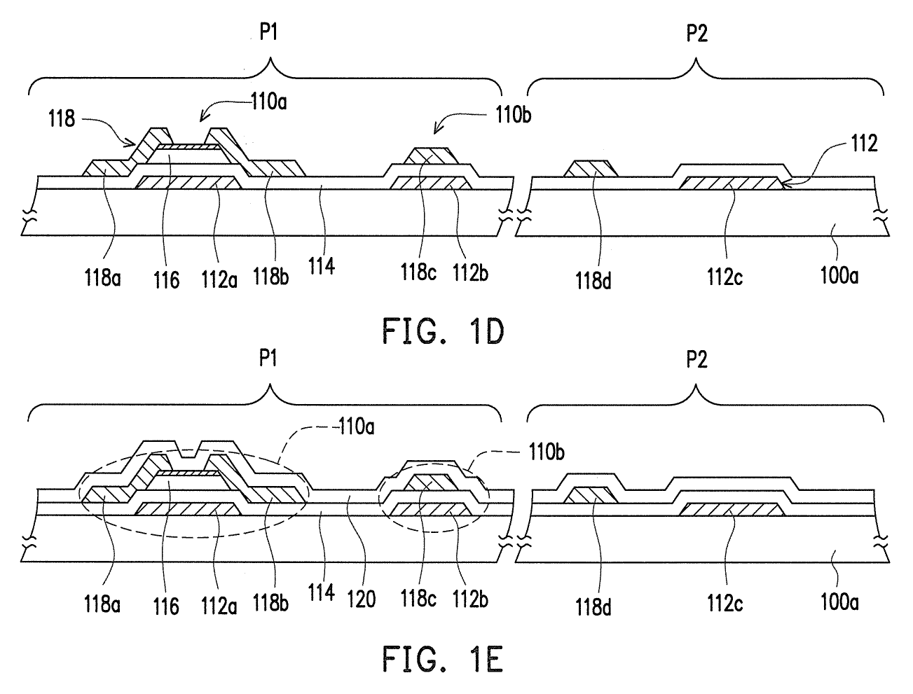

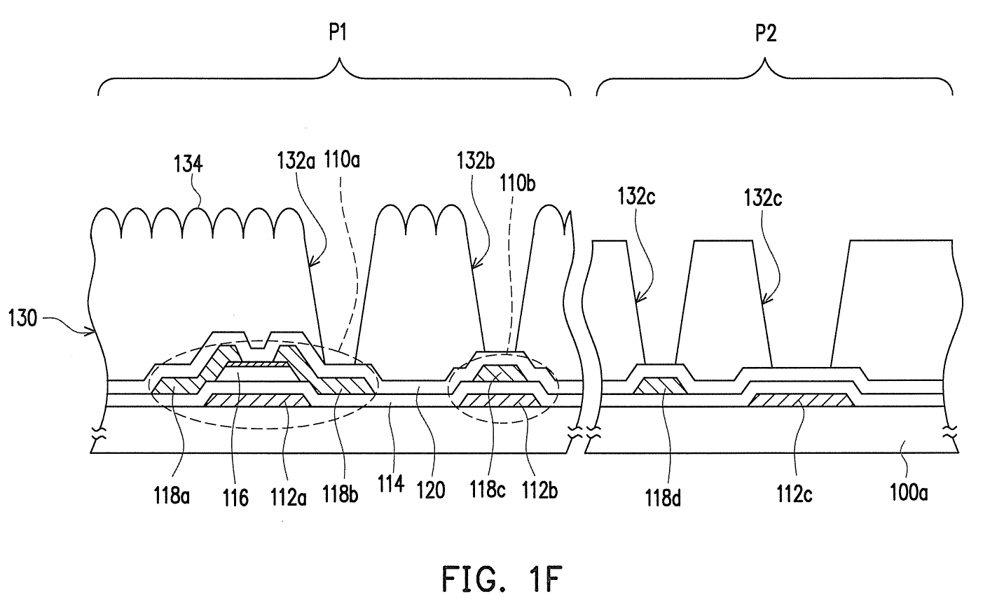

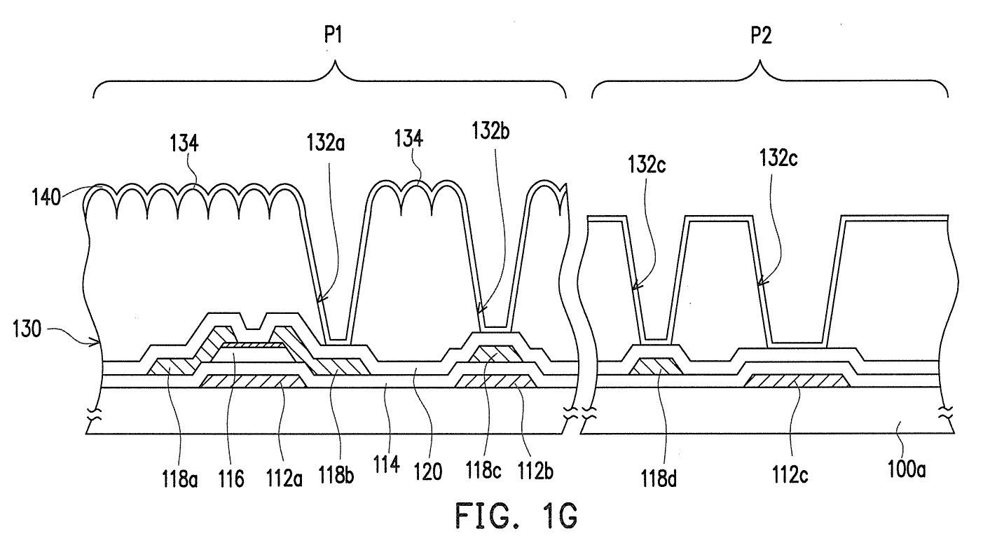

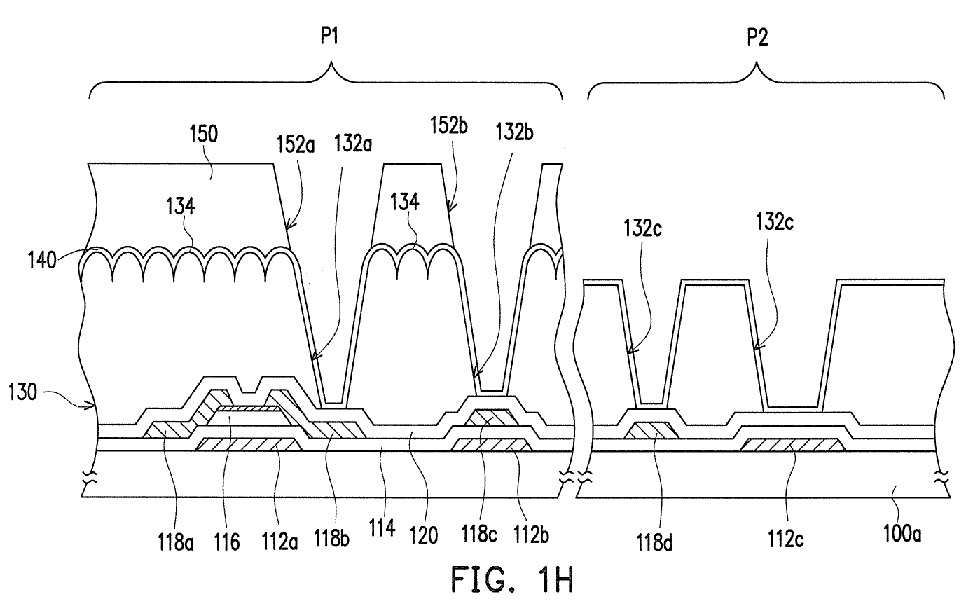

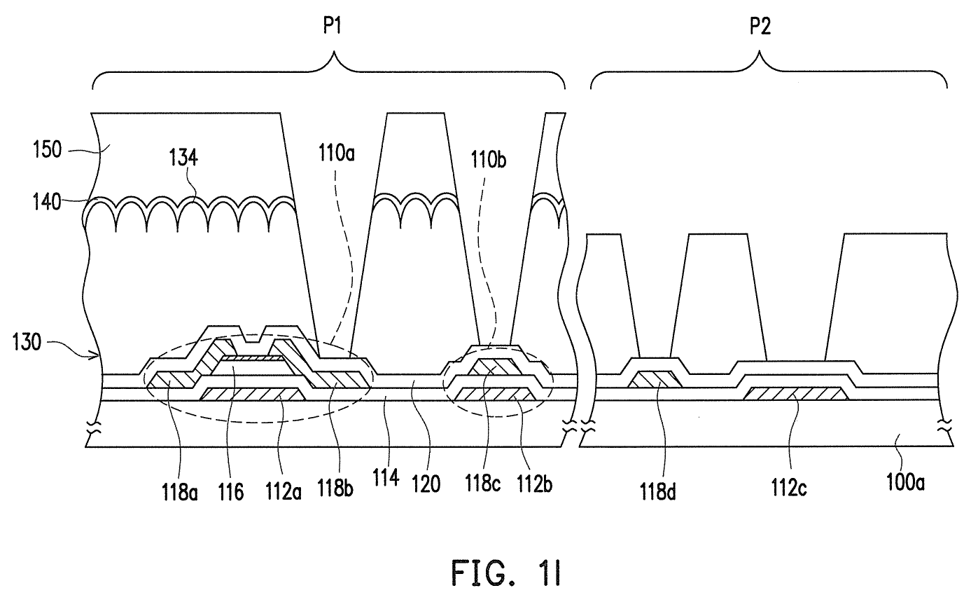

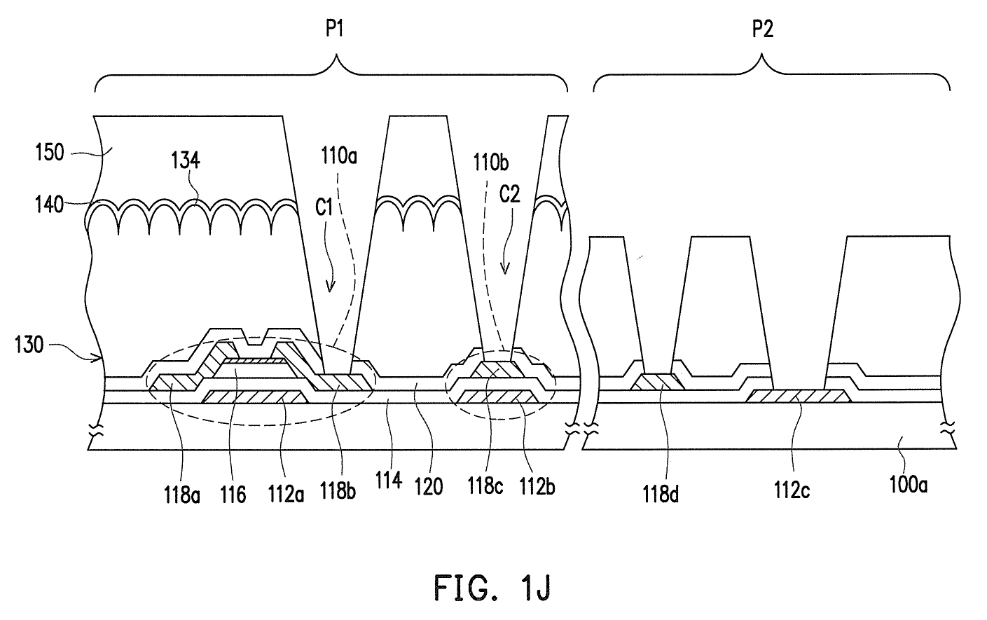

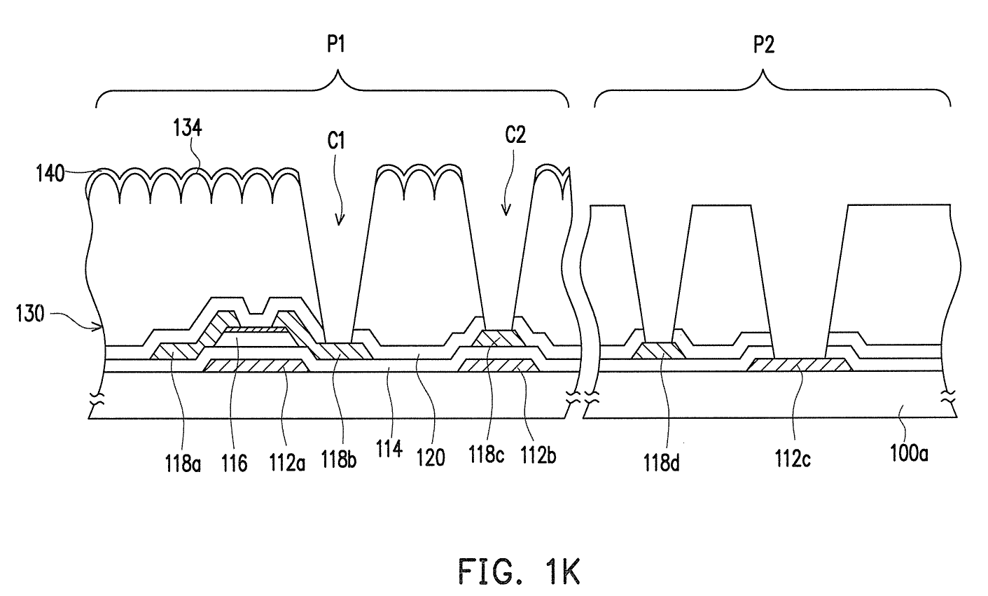

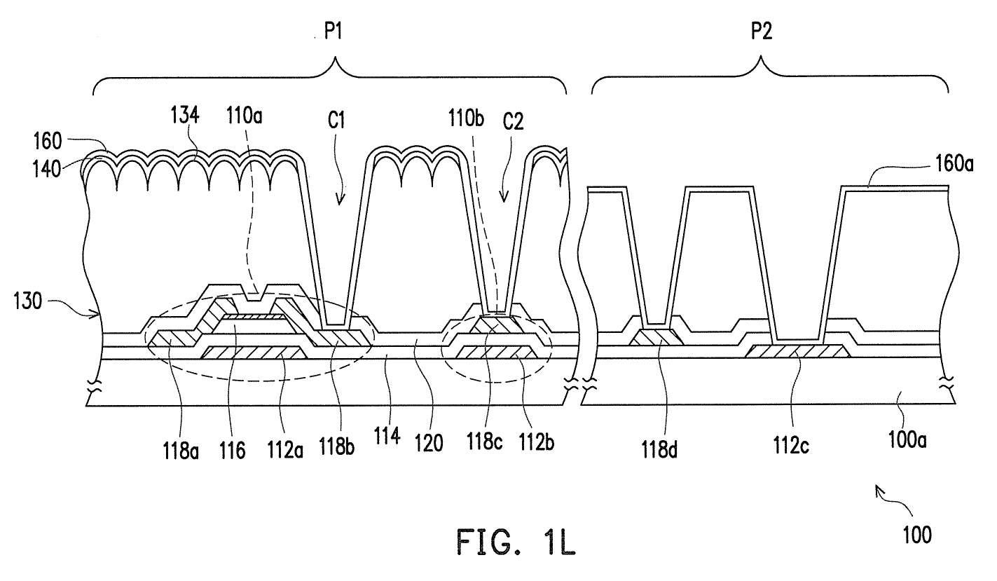

FIGS. 1A-1L are sectional diagrams illustrating the method of fabricating a pixel structure according to an embodiment of the present invention. Referring to FIG. 1A, first, a substrate 100a is provided, wherein the substrate 100a has a pixel region P1 and a pad region P2. Next, a first metal layer 112 is formed on the substrate 100a. The first metal layer 112 includes a gate 112a, a lower electrode 112b and a pad 112c, wherein the gate 112a and the lower electrode 112b are located within the pixel region P1 of the substrate 100a and the pad 112c is located within the pad region P2 of the substrate 100a.

Note that the diagrams of the embodiment exemplarily target a reflective pixel structure, but the present invention is preferably applicable to a transflective pixel structure or a micro-reflective pixel structure. In addition, in the diagrams of the embodiment, the pad region P2 is exemplarily a pad region of scan lines. In fact, a pad region of data lines (not shown in the diagrams) has the similar structure to that of the pad region of scan lines except that the pad of the pad region of data lines belongs to the second metal layer, but the pad 112c of the pad region P2 of scan lines shown in the diagrams belongs to the first metal layer 112. Moreover, the structure of the pad region P2 is not limited to the structure shown in the following fabricating flow; that is, no matter the pad region P2 is exemplarily a pad region of scan lines or a pad region of data lines, the pad region P2 has a first metal layer and a second metal layer, wherein the first metal layer and the second metal layer are simultaneously present, and the other conductive layer is used to across connect the above-mentioned two metal layers or the stacking structure of the above-mentioned two metal layers. In other embodiments, the pixel structure design is described mainly targeting the pixel region P1 only without considering the design of the pad region P2.

In the embodiment, the material of the substrate 110a includes: inorganic transparent material (for example, glass, quartz or other appropriate materials, or a combination of the above-mentioned materials); organic transparent material (for example, polyolefines, polyacyls, polyalcohols, polyesters, rubber, thermoplastic polymer, thermosolid polymer, poly-aromatic-hydrocarbons, poly-methyl-methacrylates, polycarbonates, or other appropriate materials, or a ramification of the above-mentioned materials, or a combination of the above-mentioned materials); inorganic opaque material (for example, silicon plate, ceramic or other appropriate materials, or a combination of the above-mentioned materials); or a combination of the above-mentioned materials.

The material of the first metal layer 112 formed on the substrate 100a is, preferably but not limited to by the present invention, a metal material suitable to conduct a wet etching process on. In other embodiments, the material of the first metal layer 112 is a metal material suitable to conduct a dry etching process on. The first metal layer 112 can be a single layer structure or a multi-layers structure, and the first metal layer 112 in the embodiment is for example, a molybdenum layer structure, a molybdenum-aluminium stacked layers structure or a molybdenum-aluminium-molybdenum stacked layers structure, which the present invention is not limited to. In other embodiments, the material of the first metal layer 112 can be a metal such as gold, silver, copper, tin, lead, haffium, tungsten, molybdenum, neodymium, titanium, tantalum, aluminium or zinc; an alloy of the above-mentioned metals; an oxide of the above-mentioned metals; a nitride of the above-mentioned metals; or a combination of the above-mentioned materials.

Next referring to FIG. 1B, an insulating layer 114 is formed on the first metal layer 112 to cover the gate 112a of the pixel region P1, the lower electrode 112b and the pad 112c of the pad region P2. In the embodiment, the insulating layer 114 can be a single layer structure or a multi-layers structure, and the material of the insulating layer 114 includes, for example, inorganic material (for example, silicon oxide, silicon nitride, silicon nitride oxide, silicon carbide, hafnium oxide, aluminium oxide or other materials, or a combination of the above-mentioned materials); an organic material (for example, photoresist material, enzocyclobutane (BCB), cycloolefins, polyimides (PIs), polyamides, polyesters, polyalcohols, poly-ethylene-oxides, polybenzenes, resins, polyethers, polyketides or other appropriate materials, or a combination of the above-mentioned materials); or a combination of the above-mentioned materials.

Next referring to FIG. 1C, an active layer 116 is formed on the insulating layer 114 over the gate 112a. In more detail, in the embodiment, the material of the active layer 116 can be amorphous silicon (a-Si), monocrystal-silicon, microcrystal silicon, polysilicon, or an N-type doped silicide with one of the crystal lattice types of the above-mentioned silicon, or a P-type doped silicide with one of the crystal lattice types of the above-mentioned silicon, or germanium silicide with one of the crystal lattice types of the above-mentioned silicon, or other materials, or a combination of the above-mentioned materials. The active layer 116 can be a single layer structure or a multi-layers structure. For example, the active layer 116 can be a single layer structure composed of a-Si and/or N-type heavily doped a-Si or a double-layers structure composed of a-Si and N-type heavily doped a-Si, wherein the layers can be horizontally arranged and/or vertically arranged. In the embodiment, the active layer 116 is exemplarily a double-layers structure composed of a-Si (i.e. a channel layer) and N-type heavily doped a-Si (i.e. ohmic contact layer), which the present invention is not limited to.

Next referring to FIG. 1D, a second metal layer 118 is formed on the insulating layer 114, wherein the second metal layer 118 includes a source 118a and a drain 118b both over a part of the active layer 116 located within the pixel region P1, an upper electrode 118c over the lower electrode 112b and a conductive pattern 118d located within the pad region P2, wherein the source 118a is separated with the drain 118b. At the time, the switching device 110a and the storage capacitor 110b on the substrate 100a are almost completed. Note that the above described fabricating method and the structures of the switching device 110a and the storage capacitor 110b are a preferable example of the embodiment of the present invention, which the present invention is not limited to and can be implemented other ways. The material of the second metal layer 118 formed on the insulating layer 114 is, preferably but not limited to by the present invention, a metal material suitable to conduct a wet etching process on. In other embodiments, the material of the second metal layer 118 is a metal material suitable to conduct a dry etching process on. The second metal layer 118 can be a single layer structure or a multi-layers structure, and the second metal layer 118 in the embodiment is for example, a molybdenum layer structure, a molybdenum-aluminium stacked layers structure or a molybdenum-aluminium-molybdenum stacked layers structure, which the present invention is not limited to. In other embodiments, the material of the second metal layer 118 can be a metal such as gold, silver, copper, tin, lead, hafnium, tungsten, molybdenum, neodymium, titanium, tantalum, aluminium or zinc; an alloy of the above-mentioned metals; an oxide of the above-mentioned metals; a nitride of the above-mentioned metals; or a combination of the above-mentioned materials.

Note that the switching device 110a and the structure thereof in the present invention is exemplarily a bottom-gate structure, which the present invention is not limited to. In other embodiments, the above-mentioned bottom-gate structure can be changed into a top-gate structure by switching the sequence of forming the first metal layer 112 and the active layer 116 on the substrate 100a. For example, the active layer 116 is formed on the substrate 100a, followed by forming an insulating layer 114 on the active layer 116, wherein the insulating layer 114 covers the active layer 116 located within the pixel region P1. Then, the first metal layer 112 is formed on the substrate 100a, wherein the first metal layer 112 includes the gate 112a, the lower electrode 112b and the pad 112c of the pad region P2, and the gate 112a is on the insulating layer 114 over the active layer 116. Thereafter, the other steps are similar to the above-mentioned embodiment of the present invention.

In order to obtain a better electrical characteristic, after completing the first metal layer 112, an inner layer dielectric (ILD) (not shown) is formed on the first metal layer 112 and the insulating layer 114 to cover the layers 112 and 114. At the time, the second metal layer 118 having the top-gate structure is formed on the ILD (not shown), wherein the second metal layer 118 includes a source 118a and a drain 118b both located over a part of the active layer 116 within the pixel region P1, an upper electrode 118c over the lower electrode 112b and a conductive pattern 118d located within the pad region P2, wherein the source 118a is separated with the drain 118b. At the time, the switching device 110a and the storage capacitor 110b on the substrate 110a are almost completed.

Next referring to FIG. 1E, a protective layer 120 is formed on the substrate 100a, wherein the protective layer 120 covers the switching device 110a and the storage capacitor 110b of the pixel region P1, the conductive pattern 118d of the pad region P2 and the insulating layer 114. In the embodiment, the protection layer 120 can be a single-layer structure or a multi-layers structure and the material thereof includes: organic material (for example, photoresist material, benzocyclobutene (BCB), cycloolefins, polyimides (PIs), polyamides, polyesters, polyalcohols, poly-ethylene-oxides, polybenzenes, resins, polyethers, polyketides or other appropriate materials, or a combination of the above-mentioned materials); inorganic material (for example, silicon oxide, silicon nitride, silicon nitride oxide, or other appropriate materials, or a combination of the above-mentioned materials); or a combination of the above-mentioned materials.

Next referring to FIG. 1F, a patterned organic material layer 130 is formed on the protective layer 120, wherein a plurality of bump patterns 134 is formed on a part of the patterned organic material layer 130 and the patterned organic material layer 130 has a plurality of openings 132a, 132b and 132c. The bump patterns 134 of the embodiment are formed on the organic material layer located within the pixel region P1, which the present invention is not limited to. The bump patterns 134 can be also formed on the surface of the protective layer 120, the surface of the insulating layer 114 or other appropriate film layers. The opening 132a exposes the protective layer 120 on the drain 118b located within the pixel region P1, the opening 132b exposes the protective layer 120 over the upper electrode 118c located within the pixel region P1 and the opening 132c exposes the protective layer 120 over the partial metal layer 118d located within the pad region P2 and the protective layer 120 over the partial pad 112c located within the pad region P2.

In the embodiment, the patterned organic material layer 130 is formed by using a grey level photomask (not shown), a half-tone photomask, a multi-tone photomask or other appropriate photomasks to conduct an exposing process on an organic material layer (not shown), wherein the grey level photomask is the one having different shadings and the organic material layer is exposed with different exposure doses so as to form the patterned organic material layer 130, which has a topography with different depths after a developing process. In addition, the material of the patterned organic material layer 130 includes photoresist material, benzocyclobutene (BCB), cycloolefins, polyimides (Pls), polyamides, polyesters, polyalcohols, poly-ethylene-oxides, polybenzenes, resins, polyesters, polyketides or other appropriate materials, or a combination of the above-mentioned materials.

Next referring to FIG. 1G, a reflective layer 140 is formed on the patterned organic material layer 130 and the exposed part of the protective layer 120 so that the reflective layer 140 covers the bump patterns 134 of the patterned organic material layer 130 and the part of the protective layer 120. In other words, the reflective layer 140 covers both whole the pixel region P1 and whole the pad region P2, or the reflective layer 140 is conformally formed on both whole the pixel region P1 and whole the pad region P2. In addition, in the embodiment, the reflective layer 140 can be a single layer structure or a multi-layers structure and the material thereof can be aluminium, aluminium alloy, silver or other metals with high reflectivity. In other embodiments, the above-mentioned bump patterns 134 of the present invention can be formed on the surface of the reflective layer 140.

Next referring to FIG. 1H, a first patterned photoresist layer 150 is formed on the reflective layer 140 of the pixel region P1 and has a plurality of openings 152a and 152b. In more detail, the first patterned photoresist layer 150 exposes the reflective layer 140 located within the pad region P2, the openings 152a and 152b of the first patterned photoresist layer 150 expose the partial reflective layer 140 located within the pixel region P1, the opening 152a is substantially corresponding to the opening 132a and the opening 152b is substantially corresponding to the opening 132b.

Next referring to FIGS. 1I and 1J, the first patterned photoresist layer 150 is taken as an etching mask to remove the exposed partial reflective layer 140 located within the pixel region P1 and the partial protective layer 120 under the exposed partial reflective layer 140 so as to form a first contact hole C1 and a second contact hole C2, wherein the first contact hole C1 exposes the drain 118b of the switching device 110a and the second contact hole C2 exposes the upper electrode 118c of the storage capacitor 110b. Then, within the pad region P2, the reflective layer 140 is completely removed, a part of the protective layer 120 is removed to expose a part of the conductive pattern 118d, and a part of the protective layer 120 and a part of the insulating layer 114 are removed to expose a part of the pad 112c. Note that when removing the partial protective layer 120 (for example, within the pixel region P1) under the exposed partial reflective layer 140, the first patterned photoresist layer 150 and the patterned organic material layer 130 are taken as an etching mask; when removing the partial protective layer 120 (for example, within the pad region P2) exposed by the patterned organic material layer 130, the patterned organic material layer 130 is taken as an etching mask. In the embodiment, the preferred method of removing the exposed partial reflective layer 140 and the partial protective layer 120 under the exposed partial reflective layer 140 includes wet etching, which the present invention is not limited to and the method can also include an appropriate dry etching.

In more detail, in the embodiment, the method of removing the exposed reflective layer 140 and the protective layer 120 under the exposed partial reflective layer 140 is to conduct an in-situ process. That is, to remove the exposed reflective layer 140 and the protective layer 120 under the exposed partial reflective layer 140, the reflective layer 140 and the protective layer 120 are sequentially etched in a same reaction chamber but with different etching fluids. In other words, only a single photolithograph process is conducted, or a single patterned photoresist layer or a same patterned photoresist layer is used as an etching mask to simultaneously etch the reflective layer 140 and the protective layer 120.

Next referring to FIG. 1K, the first patterned photoresist layer 150 is removed to expose the reflective layer 140. Next referring to FIG. 1L, a pixel electrode 160 is formed on the reflective layer 140 and a part of the patterned organic material layer 130 both located within the pixel region P1, and a protection electrode 160a is formed on the patterned organic material layer 130 of the pad region P2. Preferably, the pixel electrode 160 is conformally formed on the pixel region P1 and the protection electrode 160a is conformally formed on the pad region P2. The pixel electrode 160 herein is electrically connected to the drain 118b of the switching device 110a via the first contact hole C1 and electrically connected to the upper electrode 118c of the storage capacitor 110b via the second contact hole C2. The conductive pattern 118d and the pad 112c are electrically connected to each other through the protection electrode 160a. At the time, the pixel structure 100 is almost completed.

In more detail, the method of forming the pixel electrode 160 and the protection electrode 160a is, for example but not limited to by the present invention, to conduct a sputtering process based on physical vapor deposition (PVD); the other processes include screen printing, ink-jetting or other appropriate methods. The pixel electrode 160 and the protection electrode 160a can be a single layer structure or a multi-layers structure, and the materials thereof depend on the display model of the pixel structure 100. For example, the materials of the pixel electrode 160 and the protection electrode 160a can be transparent conductive material, for example, indium tin oxide (ITO), indium zinc oxide (IZO), indium tin zinc oxide (ITZO), hafnium oxide, zinc oxide, aluminium oxide, aluminium tin oxide, aluminium zinc oxide, cadmium tin oxide, cadmium zinc oxide or a combination of the above-mentioned materials. The pixel electrode 160 and the protection electrode 160a are preferably simultaneously formed, which the present invention is not limited to; i.e., they can be separately formed, not at the same time.

Since in the present invention, a same patterned photoresist layer is used as an etching mask to remove the exposed partial reflective layer 140 and the patterned protective layer 120 under the exposed partial reflective layer 140, and the above-mentioned removing steps are sequentially conducted by using the in-situ process; therefore, in comparison with the conventional fabricating method of a pixel structure of a reflective LCD, the present embodiment is advantageous in saving at least a photolithograph process, which can reduce the number of the photomasks, short the process time of the pixel structure 100 and reduce the production cost. In the embodiment, the first metal layer 112 and the second metal layer 118 are, exemplarily but not limited to by the present invention, a molybdenum layer structure or a molybdenum-aluminium stacked layers structure where a wet etching process is conducted on. Since the wet etching process requires a shorter process time than that of the dry etching process, therefore, the production capability is promoted. Besides, during conducting the wet etching process, the protective layer 120 is able to protect the second metal layer 118 from being eroded by the etching fluid.

Note that the above-mentioned embodiment exemplarily targets a reflective pixel structure, hence the reflective layer 140 covers whole the pixel region P1. The present invention is also applicable to a transflective pixel structure or a micro-reflective pixel structure. When the above-mentioned embodiment is used to fabricate a transflective pixel structure or a micro-reflective pixel structure, the pixel region P1 of the substrate 100a can be divided into at least a reflective region and at least a transmittive region (not shown) or at least a micro-reflective region and at least a transmittive region (not shown); during the successive process of forming the patterned organic material layer 130 and the reflective layer 140, the bump patterns 134 on the patterned organic material layer 130 and the reflective layer 140 are formed within the reflective region only.

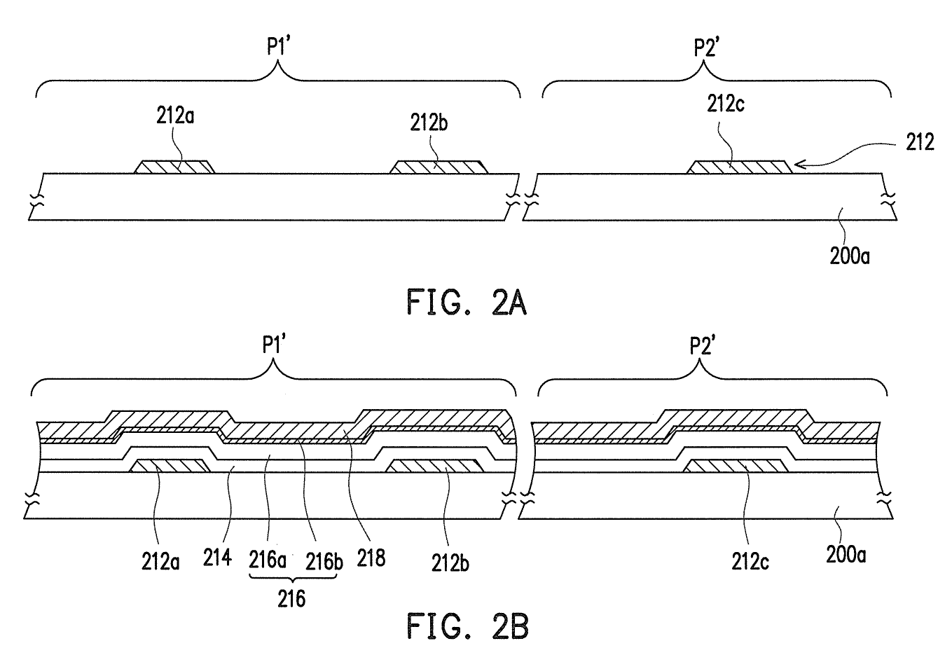

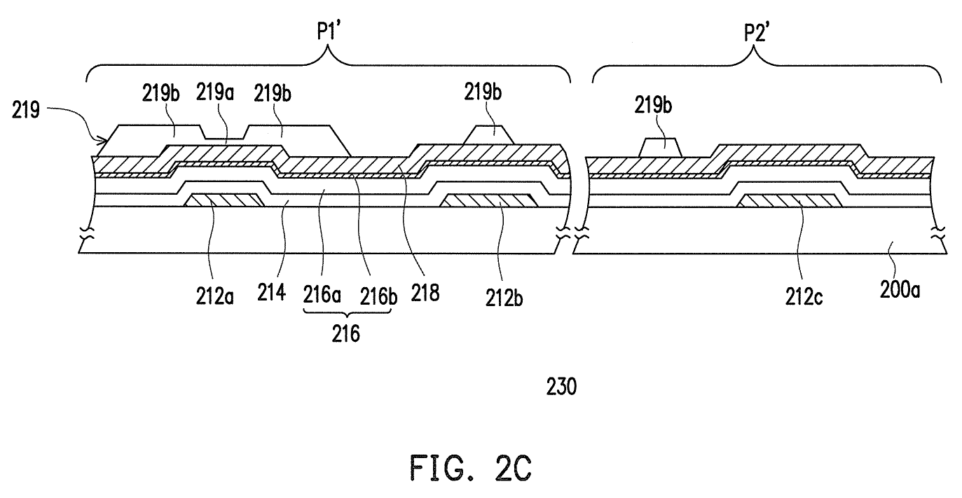

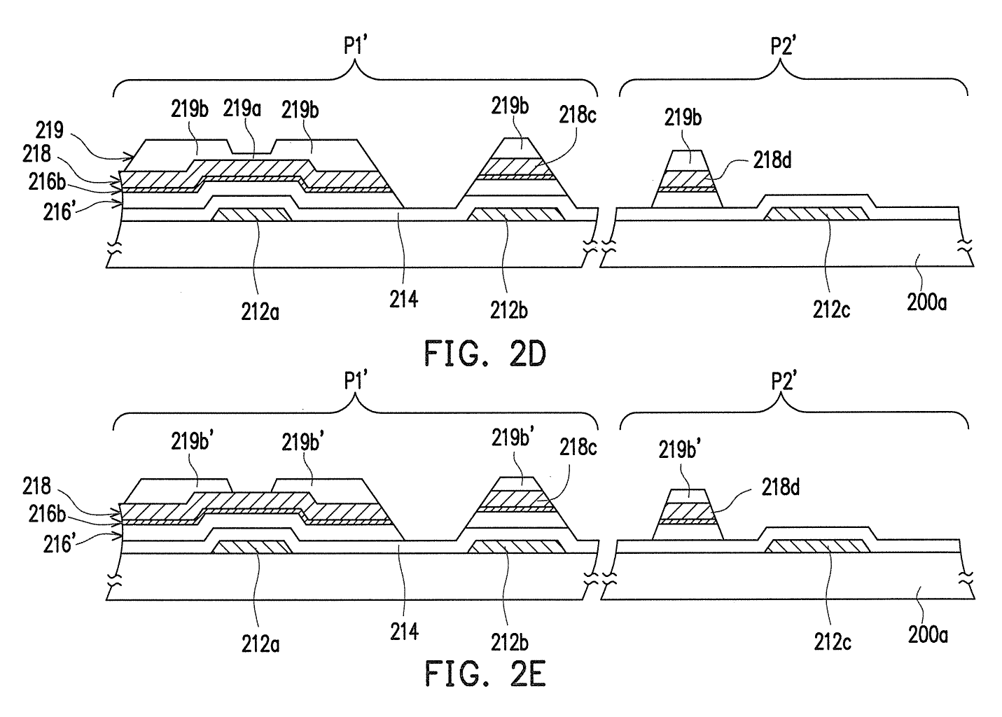

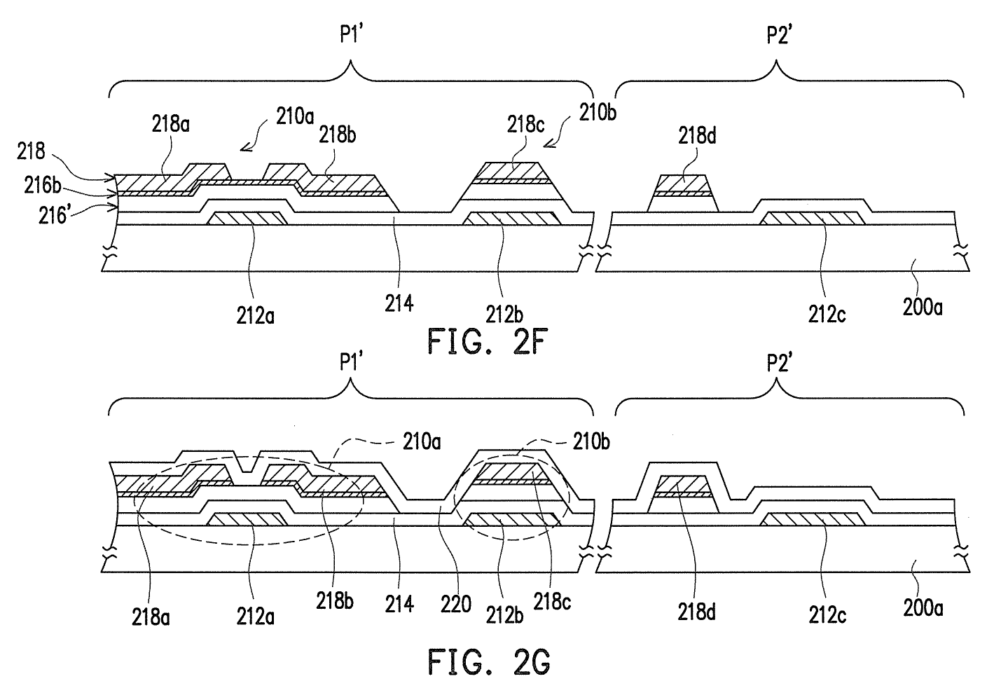

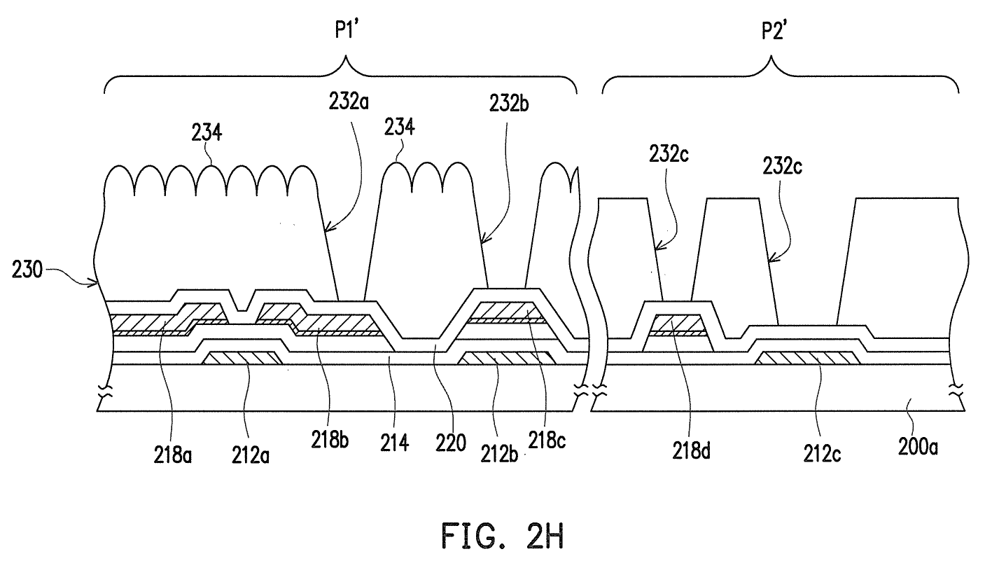

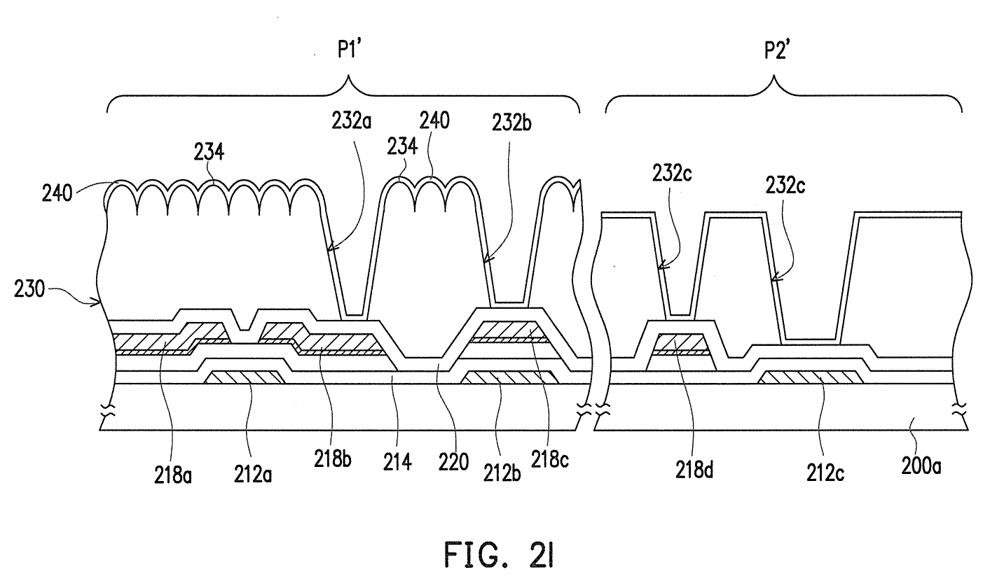

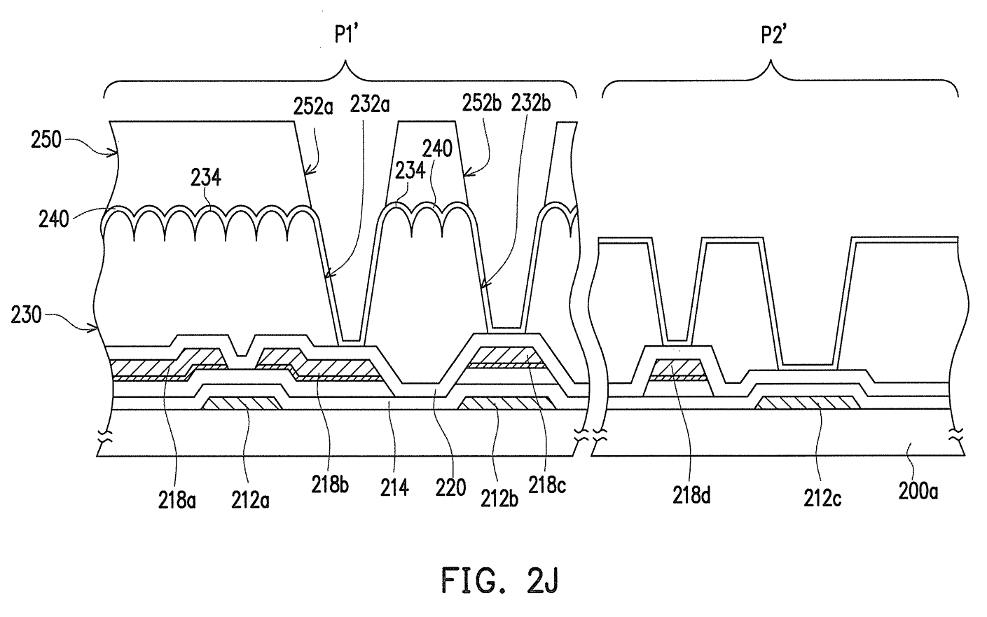

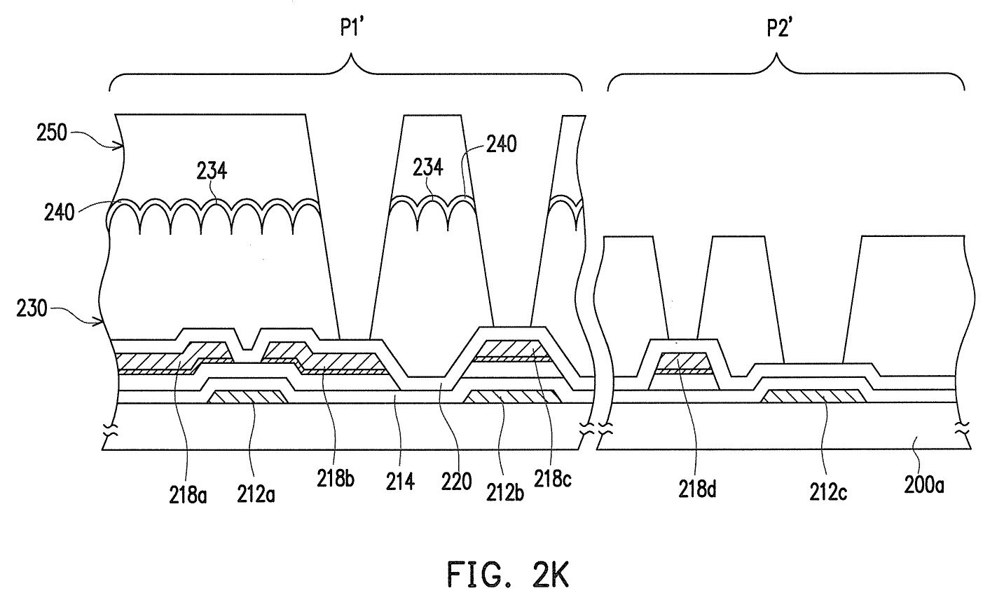

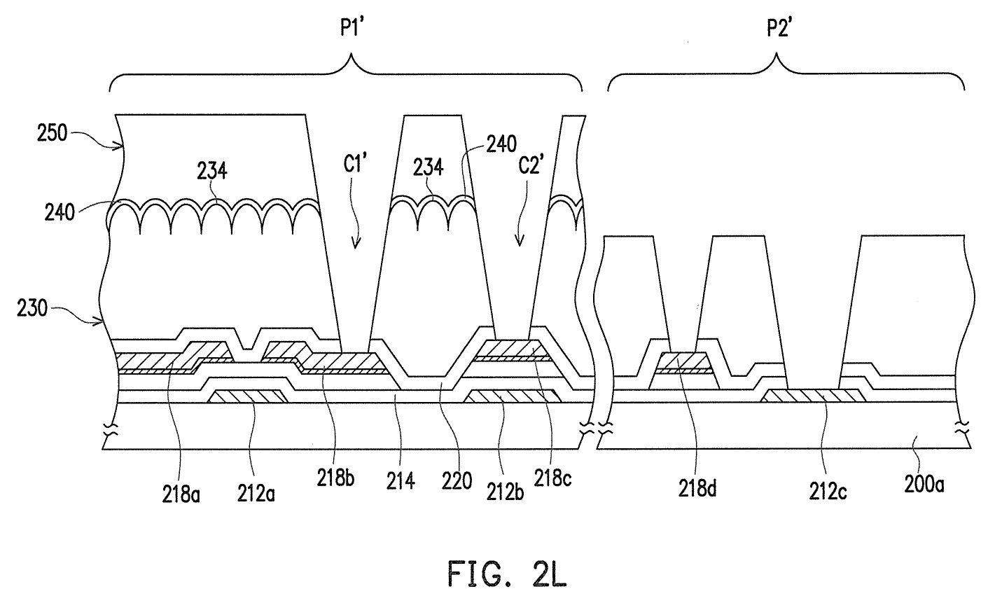

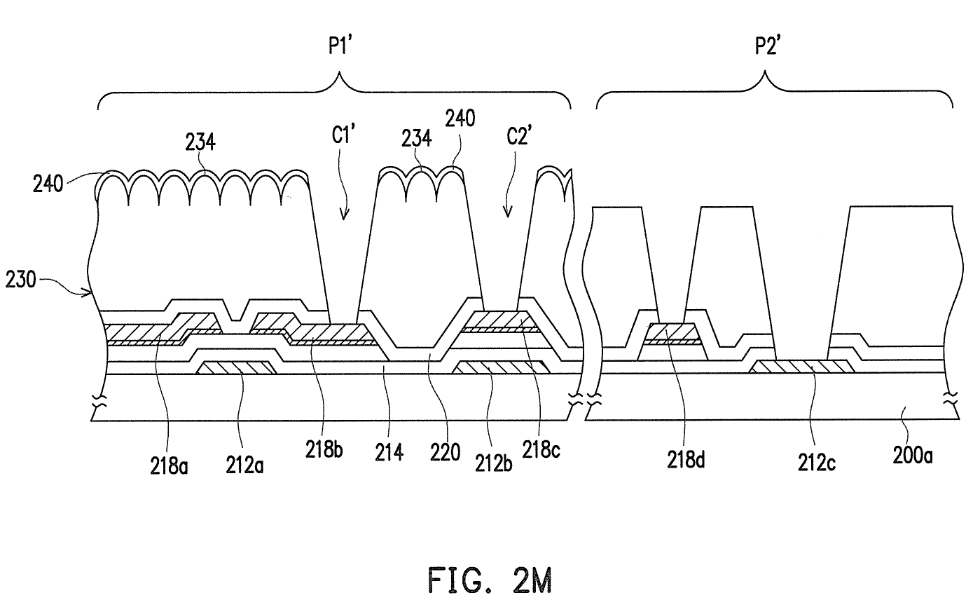

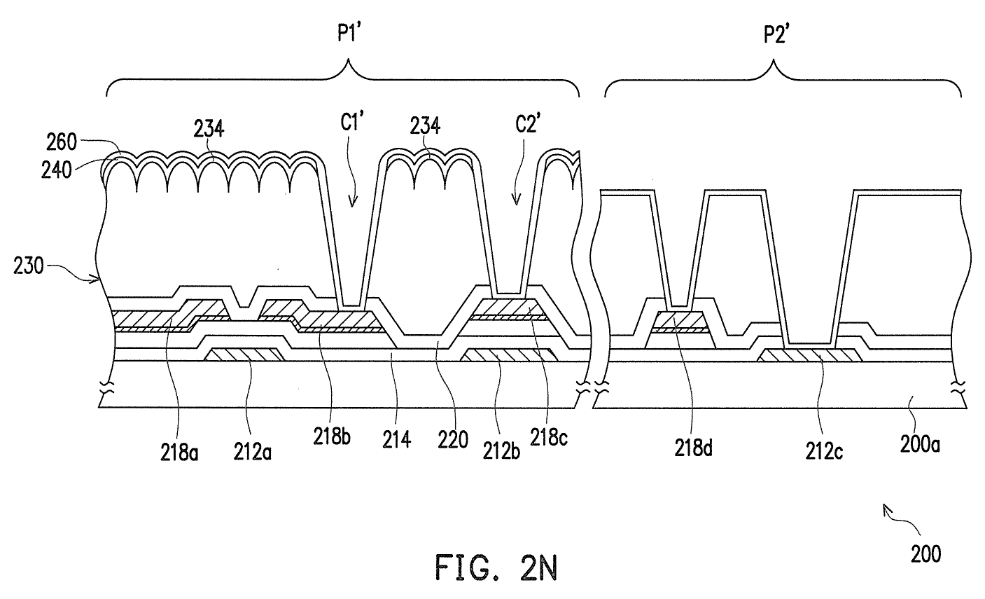

FIGS. 2A-2N are sectional diagrams illustrating the method of fabricating a pixel structure according to another embodiment of the present invention. Referring to FIG. 2A, first, a substrate 200a is provided, wherein the substrate 200a has a pixel region P1′ and a pad region P2′. Next, a first metal layer 212 is formed on the substrate 200a. The first metal layer 212 includes a gate 212a, a lower electrode 212b and a pad 212c, wherein the gate 212a and the lower electrode 212b are located within the pixel region P1′ of the substrate 200a and the pad 212c is located within the pad region P2′ of the substrate 200a. The materials of the substrate 200a and the first metal layer 212 and the structure and design of the pad 212c are the same as the above-mentioned embodiment (corresponding to the depictions of the substrate 100a and the first metal layer 112 shown in FIG. 1A), hence they are omitted to describe. In other embodiments, the pixel structure design is described mainly targeting the pixel region P1′ only without considering the design of the pad region P2′.

Next referring to FIG. 2B, an insulating layer 214, a semiconductor layer 216 and a second metal layer 218 are sequentially formed on the first metal layer 212, where the insulating layer 214 covers the gate 212a of the pixel region P1′, the lower electrode 212b and the pad 212c of the pad region P2′; the semiconductor layer 216 covers the insulating layer 214; the second metal layer 218 covers the semiconductor layer 216. In other words, the insulating layer 214, the semiconductor layer 216 and the second metal layer 218 are sequentially stacked together. In the embodiment, the semiconductor layer 216 comprises a channel layer 216a and an ohmic contact layer 216b, and the channel layer 216a and the ohmic contact layer 216b are vertically arranged, which the present invention is not limited to, i.e., the channel layer 216a and ohmic contact layer 216b can be arranged horizontally too. The material of the channel layer 216a herein includes a-Si, monocrystal-silicon, microcrystal silicon, polysilicon or other appropriate materials, or a combination of the above-mentioned materials. In the embodiment, the channel layer 216a is exemplarily made of 1-Si, which the present invention is not limited to. The material of the ohmic contact layer 216b includes N-type doped a-Si, P-type doped a-Si, N-type doped/P-type doped monocrystal-silicon, N-type doped/P-type doped microcrystal-silicon, N-type doped/P-type doped polycrystal-silicon, or other appropriate materials, or a combination of the above-mentioned materials. In the embodiment, the ohmic contact layer 216b is exemplarily made of N-type heavily doped a-Si, which the present invention is not limited to. The materials of the insulating layer 214 and the second metal layer 218 are the same as the above-mentioned embodiment (corresponding to the depictions of the insulating layer 114 shown in FIG. 1B and the second metal layer 118 shown in FIG. 1D), hence they are omitted to describe.

Next referring to FIG. 2C, a second patterned photoresist layer 219 is formed on the second metal layer 218, wherein the second patterned photoresist layer 219 has a first portion 219a and a second portion 219b, the first portion 219a is located over the gate 212a, and the second portion 219b covers the second metal layer 218 located over the gate 212a and at both sides of the gate 212a, the second metal layer 218 over the lower electrode 212b and the conductive pattern 218d of the pad region P2′.

In more detail, the second patterned photoresist layer 219 is formed by using a grey level photomask (not shown), a half-tone photomask, a multi-tone photomask or other appropriate photomasks to conduct an exposing process on a photoresist layer (not shown), wherein the grey level photomask is the one having different shadings and the photoresist layer is exposed with different exposure doses so as to form the first portion 219a and the second portion 219b of the second patterned photoresist layer 219 and to expose a part of the second metal layer 218 after a developing process, wherein the second patterned photoresist layer 219 has a topography with different depths and the thickness of the first portion 219a is substantially less than the thickness of the second portion 219b.

Next referring to FIG. 2D, the second patterned photoresist layer 219 is taken as a mask to etch the exposed partial second metal layer 218 and the film layer (for example, the semiconductor layer 216) under the second metal layer 218 so as to pattern the second metal layer 218 and the semiconductor layer 216 and to define the active layer 216′ over the gate 212a, the upper electrode 218c over the lower electrode 212b, and the conductive pattern 218d within the pad region P2′. At the time, the area not shaded by the second patterned photoresist layer 219 would expose a part of the insulating layer 214. In more detail, the material of the active layer 216′ in the embodiment is the same as the material of the channel layer 216a of the semiconductor layer 216 (shown in FIG. 2B). In the embodiment, the active layer 216′ is exemplarily made of amorphous silicon, which the present invention is not limited to.

Next referring to FIG. 2E, an ashing process is conducted on the second patterned photoresist layer 219 to control the etched thickness of the second patterned photoresist layer 219, which is etched during the ashing process. After that, the first portion 219a is completely removed to form the second portion 219b with a thinner thickness, and the second portion 219b with a thinner thickness exposes a part of the second metal layer 218 over the active layer 216′.

Next referring to FIGS. 2F and 2G, the second portion 219b with a thinner thickness of the second patterned photoresist layer 219 is taken as a mask to remove the second metal layer 218 over the active layer 216′ so as to define the source 218a and the drain 218b and to remove a part of the ohmic contact layer 216b so as to expose a part of the active layer 216′, wherein the source 218a is separated with the drain 218b. After that, the second portion 219b with a thinner thickness is removed to expose the source 218a, the drain 218b and the upper electrode 218c all located within the pixel region P1′ and the conductive pattern 218d of the pad region P2′, as shown in FIG. 2G. Specially, in the embodiment, the active layer 216′ serves as the electronic channel between the source 218a and the drain 218b, and the ohmic contact layer 216b is able to reduce the contact impedance between the source 218a/drain 218b of the second metal layer 218 and the active layer 216′. At the time, the switching device 210a and the storage capacitor 210b on the substrate 200a are almost completed. The present embodiment exemplarily targets a bottom-gate structure; but the present invention can also target the top-gate structure of the above-mentioned embodiment. Note that the above-mentioned fabricating method and the structures of the switching device 210a and the storage capacitor 210b are a preferred example only, which the present invention is not limited to and other appropriate fabricating method and structures are allowed.

Continuing to FIG. 2G, a protective layer 220 is formed on the substrate 200a, wherein the protective layer 220 covers the switching device 210a and the storage capacitor 210b of the pixel region P1′ and the conductive pattern 218d of the pad region P2′. The material of the protective layer 220 is the same as the above-mentioned embodiment (corresponding to the depictions of the protective layer 120 in FIG. 1E), hence it is omitted to describe.

Next referring to FIG. 2H, a patterned organic material layer 230 is formed on the protective layer 220, wherein a plurality of bump patterns 234 is formed on a part of the patterned organic material layer 230 and the patterned organic material layer 230 has a plurality of openings 232a, 232b and 232c. The bump patterns 234 of the embodiment are formed on the organic material layer located within the pixel region P1′, which the present invention is not limited to. The bump patterns 234 can be also formed on the surface of the protective layer 220, the surface of the insulating layer 214, or other appropriate film layers. The opening 232a exposes the protective layer 220 on the drain 218b located within the pixel region P1′, the opening 232b exposes the protective layer 220 over the upper electrode 218c located within the pixel region P1′ and the opening 232c exposes the protective layer 220 over the partial metal layer 218d located within the pad region P2′ and the protective layer 220 over the partial pad 212c located within the pad region P2′.

In the embodiment, the patterned organic material layer 230 is formed by using a grey level photomask (not shown), a half-tone photomask, a multi-tone photomask or other appropriate photomasks to conduct an exposing process on an organic material layer (not shown), wherein the grey level photomask is the one having different shadings and the organic material layer is exposed with different exposure doses so as to form the patterned organic material layer 230, which has a topography with different depths after a developing process. In addition, the material of the patterned organic material layer 230 is the same as the above-mentioned embodiment (corresponding to the depictions of the patterned organic material layer 130 in FIG. 1F), hence it is omitted to describe.

Next referring to FIG. 21, a reflective layer 240 is formed on the patterned organic material layer 230 and the exposed part of the protective layer 220 so that the reflective layer 240 covers the bump patterns 234 of the patterned organic material layer 230 and the part of the protective layer 220. In other words, the reflective layer 240 covers both whole the pixel region P1′ and whole the pad region P2′. That is, the reflective layer 240 is conformally formed on both whole the pixel region P1′ and whole the pad region P2′. In addition, in the embodiment, the reflective layer 240 can be a single layer structure or a multi-layers structure and the material thereof can be aluminium, aluminium alloy, silver or other metals with high reflectivity. The disposing positions of the above-mentioned bump patterns 234 in the embodiment are an example only; in other unshown embodiments, the bump patterns 234 can be formed on the surface of the reflective layer 240.

Next referring to FIG. 2J, a first patterned photoresist layer 250 is formed on a part of the reflective layer 240 of the pixel region P1′ and has a plurality of openings 252a and 252b. In more detail, the first patterned photoresist layer 250 exposes the reflective layer 240 located within the pad region P2′, the openings 252a and 252b of the first patterned photoresist layer 250 expose the partial reflective layer 240, the opening 252a is substantially corresponding to the opening 232a and the opening 252b is substantially corresponding to the opening 232b.

Next referring to FIGS. 2K and 2L, the first patterned photoresist layer 250 is taken as an etching mask to remove the exposed partial reflective layer 240 located within the pixel region P1′ and the partial protective layer 220 under the exposed partial reflective layer 240 so as to form a first contact hole C1′ and a second contact hole C2′, wherein the first contact hole C1′ exposes the drain 218b of the switching device 210a and the second contact hole C2′ exposes the upper electrode 218c of the storage capacitor 210b. Then, within the pad region P2′, the reflective layer 240 is completely removed, a part of the protective layer 220 is removed to expose a part of the conductive pattern 218d, and a part of the protective layer 220 and a part of the insulating layer 214 are removed to expose a part of the pad 212c. Note that when removing the partial protective layer 220 (for example, within the pixel region P1′) under the exposed partial reflective layer 240, the first patterned photoresist layer 250 and the patterned organic material layer 230 are taken as an etching mask; when removing the partial protective layer 220 (for example, within the pad region P2′) exposed by the patterned organic material layer 230, the patterned organic material layer 230 is taken as an etching mask. In the embodiment, the preferred method of removing the exposed partial reflective layer 240 and the partial protective layer 220 under the exposed partial reflective layer 240 includes wet etching, which the present invention is not limited to and the method can also include an appropriate dry etching.

In more detail, in the embodiment, the method of removing the exposed reflective layer 240 and the protective layer 220 under the exposed partial reflective layer 240 is to conduct an in-situ process. That is, to remove the exposed partial reflective layer 240 and the protective layer 220 under the exposed partial reflective layer 240, the reflective layer 240 and the protective layer 220 are sequentially etched in a same reaction chamber but with different etching fluids. In other words, only a single photolithograph process is conducted, or a single patterned photoresist layer or a same patterned photoresist layer is used as an etching mask to simultaneously etch the reflective layer 240 and the protective layer 220.

Next referring to FIG. 2M, the first patterned photoresist layer 250 is removed to expose the reflective layer 240. Next referring to FIG. 2N, a pixel electrode 260 is formed on the reflective layer 240 and a part of the patterned organic material layer 230 both located within the pixel region P1′, and a protection electrode 260a is formed on the patterned organic material layer 230 of the pad region P2′. Preferably, the pixel electrode 260 is conformally formed on the pixel region P1′ and the protection electrode 260a is conformally formed on the pad region P2′. The pixel electrode 260 herein is electrically connected to the drain 218b of the switching device 210a via the first contact hole C1′ and to the upper electrode 218c of the storage capacitor 210b via the second contact hole C2′. The conductive pattern 218d and the pad 212c are electrically connected to each other through the protection electrode 260a. In the embodiment, the material of the pixel electrode 260 is the same as the above-mentioned embodiment (corresponding to the depictions of the pixel electrode 160 in FIG. 1L), hence it is omitted to describe. At the time, the pixel structure 200 is almost completed. The pixel electrode 260 and the protection electrode 260a are preferably simultaneously formed, which the present invention is not limited to; i.e., they can be separately formed, not at the same time.

Similarly to the above-mentioned embodiment, at least a photolithograph process can be saved, which reduces the number of the photomasks, shorts the process time of the pixel structure 200 and reduces the production cost. If the embodiment adopts a wet etching process to etch the first metal layer 212 and the second metal layer 218, the production capability can be increased as well. Besides, during conducting the wet etching process, the protective layer 220 is able to protect the second metal layer 218 from being eroded by the etching fluid.

Note that the above-mentioned embodiment exemplarily targets a reflective pixel structure, hence the reflective layer 240 covers whole the pixel region P1′. The present invention is also applicable to a transflective pixel structure or a micro-reflective pixel structure. If the above-mentioned embodiment is used to fabricate a transflective pixel structure, the pixel region P1′ of the substrate 200a can be divided into at least a reflective region and at least a transmittive region (not shown) or at least a micro-reflective region and at least a transmittive region (not shown); during the successive process of forming the patterned organic material layer 230 and the reflective layer 240, the bump patterns 234 on the patterned organic material layer 230 and the reflective layer 240 are formed within the reflective region only.

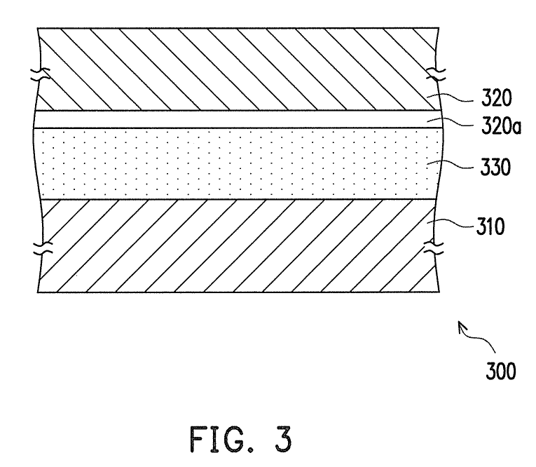

FIG. 3 is a diagram of a display panel according to an embodiment of the present invention. Referring to FIG. 3, a product of a display panel 300 provided by an embodiment of the present invention includes at least a pixel array substrate 310, another substrate 320 opposite to the pixel array substrate 310 and a display medium 330 disposed between the pixel array substrate 310 and the substrate 320. The pixel array substrate 310 herein has the pixel structure 100 as shown by FIG. 1L or the pixel structure 200 as shown by FIG. 2N. The other substrate 320 optionally has a transparent electrode 320a thereon. The method of fabricating the display panel 300 includes the method of fabricating the pixel structure 100 or the pixel structure 200, the fabricating procedure of various display panels 300 and then an assembling process so as to complete a display panel 300.

When the display medium 330 is electro-optical refractive material, for example, liquid crystal material, the display panel 300 can be transflective display panel, micro-reflective display panel, reflective display panel, color filter on array display panel (COA display panel), array on color filter display panel (AOC display panel), vertical alignment display panel (VA display panel), in-plane switching display panel (IPS display panel), multi-domain vertically alignment display panel (MVA display panel), twisted nematic display panel (TN display panel), super twisted nematic (STN display panel), patterned vertical alignment display panel (PVA display panel), super patterned vertical alignment display panel (S-PVA display panel), advanced super view display panel (ASV display panel), fringe field switching display panel (FFS display panel), continuous pinwheel alignment display panel (CPA display panel), axially symmetric aligned microcell display panel (ASM display panel), optically compensated bend display panel (OCB display panel), super in-plane switching display panel (S-IPS display panel), advanced super in-plane switching display panel (AS-IPS display panel), ultra fringe field switching display panel (UFFS display panel), anisotropic polymer-dispersed display panel, dual-view display panel, triple-view display panel, three-dimensional display panel (3-D display panel), multi-panel of display or other display panels. If the display medium 330 is electroluminescent material (EL material), the display panel 300 is called as electroluminescent display panel (ELD panel), such as phosphoresce ELD panel, fluorescent phosphoresce ELD panel or a combination of the above-mentioned modes; the display panel 300 can also be termed as self-luminescent display panel, wherein the EL material can be organic material, inorganic material or a combination of the above-mentioned materials. In terms of the molecule size of the above-mentioned materials, it can be small molecule, macromolecule or a combination of them. If the display medium 330 contains both liquid crystal material and EL material, the display panel 300 is termed as hybrid display panel or semi self-luminescent display panel.

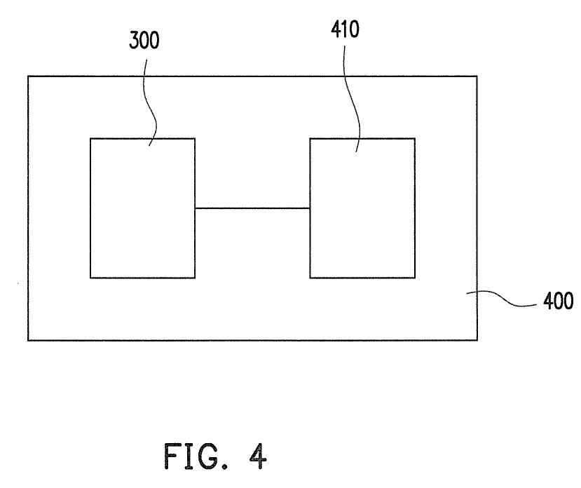

FIG. 4 is a diagram of an electro-optical apparatus according to an embodiment of the present invention. Referring to FIG. 4, the display panel 300 provided by the above-mentioned embodiment can be electrically linked to an electronic component 410 to comprise an electro-optical apparatus 400. The method of fabricating the electro-optical apparatus 400 includes the method of fabricating the display panel 300, the fabricating procedure of various electro-optical apparatuses 400 and then an assembling process so as to complete the electro-optical apparatus 400. Since in the embodiment, the display panel 300 adopts the above-mentioned the pixel structure 100 (as shown by FIG. 1L) or the pixel structure 200 (as shown by FIG. 2N) as the pixel array substrate 310 (as shown by FIG. 3); therefore, the electro-optical apparatus 400 adopting the above-mentioned pixel structure 100 or pixel structure 200 is advantageous in reducing the process time, increasing the productivity and saving the production cost.

The photo-electrical component 410 includes, for example, control component, operation component, processing component, input component, memory component, driving component, light-emitting component, protection component, sensing component, detection component or other functional components, or a combination of the above-mentioned components. The electro-optical apparatus 400 includes portable product such as handset, video camera, camera, notebook computer, game machine, watch, music player, electronic mail transceiver, global positioning system (GPS), digital photo album or similar electronic products. The photo-electrical apparatus 400 of the embodiment also includes audio/video product (for example, AV player or similar products), screen, television set, display board and panel in a projector.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a pixel structure, comprising:
providing a substrate, having a switching device and a storage capacitor thereon;
forming a protective layer on the substrate to cover the switching device and the storage capacitor;
forming a patterned organic material layer on the protective layer, wherein a plurality of bump patterns are formed on a part of the patterned organic material layer, the patterned organic material layer has a plurality of first openings to respectively expose the protective layer located over the source/drain and the protective layer located over the upper electrode of the storage capacitor;
forming a reflective layer on the patterned organic material layer and the exposed part of the protective layer;
forming a first patterned photoresist layer on a part of the reflective layer, wherein the first patterned photoresist layer has a plurality of second openings to expose a part of the reflective layer and each of the second openings is substantially corresponding to each of the first openings;
taking the first patterned photoresist layer as an etching mask to remove the exposed part of the reflective layer and the part of the protective layer located under the exposed part of the reflective layer so as to form a first contact hole exposing the source/drain of the switching device and a second contact hole exposing the upper electrode of the storage capacitor;
removing the first patterned photoresist layer; and
forming a pixel electrode on the patterned organic material layer, wherein the pixel electrode is electrically connected to the source/drain of the switching device via the first contact hole and electrically connected to the upper electrode of the storage capacitor via the second contact hole.

2. The method of fabricating a pixel structure according to claim 1, wherein the step of removing the exposed part of the reflective layer and the protective layer under the exposed part of the reflective layer is conducted by using an in-situ process.

3. The method of fabricating a pixel structure according to claim 1, wherein the step of forming the patterned organic material layer is to conduct an exposing process on an organic material layer by using a grey level photomask.

4. The method of fabricating a pixel structure according to claim 1, wherein the method of forming the switching device and the storage capacitor comprises:
forming a first metal layer on the substrate, wherein the first metal layer comprises a gate and a lower electrode;
forming an insulating layer on the first metal layer;
forming an active layer on the insulating layer over the gate; and
forming a second metal layer on the insulating layer, wherein the second metal layer comprises the source and the drain over a part of the active layer and the upper electrode over the lower electrode.

5. The method of fabricating a pixel structure according to claim 1, wherein the method of forming the switching device and the storage capacitor comprises:
forming a first metal layer on the substrate, wherein the first metal layer comprises a gate and a lower electrode;
sequentially forming an insulating layer, a semiconductor layer and a second metal layer on the first metal layer;
forming a second patterned photoresist layer on the second metal layer, wherein the second patterned photoresist layer has a first portion and a second portion, the first portion is located over the gate, and the second portion covers two parts of the second metal layer located at both sides of the gate and the second metal layer over the lower electrode;
taking the second patterned photoresist layer as a mask to pattern the second metal layer and the semiconductor layer so as to define an active layer over the gate and an upper electrode over the lower electrode;
conducting an ashing process on the second patterned photoresist layer to remove the first portion; and
taking the second portion of the second patterned photoresist layer as a mask to remove the second metal layer over the active layer so as to define the source and the drain.

6. The method of fabricating a pixel structure according to claim 5, wherein the step of forming the second patterned photoresist layer is to conduct an exposing process on a photoresist layer by using a grey level photomask.

7. A method of fabricating a display panel, comprising the method of fabricating a pixel structure according to claim 1.

8. A method of fabricating an electro-optical apparatus, comprising the method of fabricating a display panel according to claim 7.
